(19) United States
(12) Patent Application Publication
(10) Pub. No.: US 2003/0059993 A1
(43) Pub. Date: Mar. 27, 2003

(54) Method of manufacturing semiconductor device

(75) Inventor: Katsuhiko Fukasaku, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/170,650

(22) Filed: Jun. 14, 2002

(30) Foreign Application Priority Data
Jun. 14, 2001 (JP) 2001-180012

(51) Int. Cl. H01L 21/336; H01L 21/8234

(52) U.S. Cl. 438/197; 438/295; 438/301

(57) ABSTRACT

The manufacturing method of semiconductor devices including a MOSFET according to the present invention has a step of selectively forming element isolation films on the surface of a semiconductor substrate of first conductivity type, a step of forming a well region of the first conductivity type in a selected region between the element isolation films, a step of forming a gate insulation film on the surface of the semiconductor substrate and forming a first conductive film composed of amorphous silicon on top of it, a step of forming a gate electrode in a portion above the well region of the first conductivity type by patterning the first conductive film, a step of forming an oxide film by in-situ steam generation (ISSG) method on the side faces of the gate electrode, and a step of forming a source region and a drain region formed in self-alignment with the gate electrode by implanting a second conductivity type impurity into the well region of the first conductivity type using the gate electrode and the oxide film on its side faces as a mask.

### BACKGROUND OF THE INVENTION

1. Field of the Invention

The present invention relates to a method of manufacturing a semiconductor device, and more particularly to a method of manufacturing a MOSFET semiconductor device in which an oxide film with a prescribed thickness is formed on side faces of the gate electrode.

2. Description of the Prior Art

In order to pursue higher performance of MOSFETs, there is arising a necessity of forming hyperfine devices such as those with a gate length of less than 0.1 μm by adopting a scaling. Accompanying such a trend, the effect of variations in ion implantation on the formation of the source-drain extension regions is becoming more significant. Variations in the ion implantation depend also on the shape of the gate, needless to say about the dependence on the performance of the implanting apparatus. Therefore, when the processing of a side face oxidation is employed, for example, following the formation of the gate, and if there occur variations in the thickness of the side face oxide film, they act as the cause of variations in the performance as a mask.

When polysilicon is used for the gate electrode as shown in FIG. 1, there arises a problem that the film thickness 7 is different for each grain under the influence of the plane direction of each grain because of the difference in the plane direction for each grain of polysilicon.

In a semiconductor device with a gate length of less than 0.1 μm as a result of advance in the refinement of the semiconductor devices, the overlap length ΔL of the gate length to the channel region is about 20 nm. If the variation in the thickness of the side face oxide film becomes as large as 1 nm, it represents a variation of about 5% relative to the ΔL, which is significant as an influence given to the variation of the transistor characteristics. As a result, a uniform thickness of the side face oxide film becomes necessary for fine devices with gate length of less than 0.1 μm.

### BRIEF SUMMARY OF THE INVENTION

### Object of the Invention

It is the object of the present invention to provide a method of manufacturing a semiconductor device which is capable of forming a side face oxide film having uniform thickness without being affected by the face orientation of each grain of polysilicon.

### Summary of the Invention

The method of manufacturing semiconductor devices including a MOSFET according to the present invention has a step of selectively forming element isolation films on the surface of a semiconductor substrate of first conductivity type, a step of forming a well region of the first conductivity type in a selected region between the element isolation films, a step of forming a gate insulation film on the surface of the semiconductor substrate and a first conductive film composed of amorphous silicon on top of it, a step of forming a gate electrode in a portion above the well region of the first conductivity type by patterning the first conductive film, a step of forming an oxide film on the side faces of the gate electrode by the ISSG method, and a method of forming a source region and a drain region formed in self-alignment with the gate electrode by implanting an impurity of second conductivity type in the well region of the first conductivity type with the gate electrode and the oxide film on its side faces as a mask.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a sectional view of the semiconductor device for describing the prior art;

FIG. 2 is a sectional view for describing the present invention;

FIG. 3 is a sectional view for describing the step following that in FIG. 2;

FIG. 4 is a sectional view for describing the step following that in FIG. 3;

FIG. 5 is a sectional view for describing the step following that in FIG. 4; and

FIG. 6 is a sectional view for describing the step following that in FIG. 6.

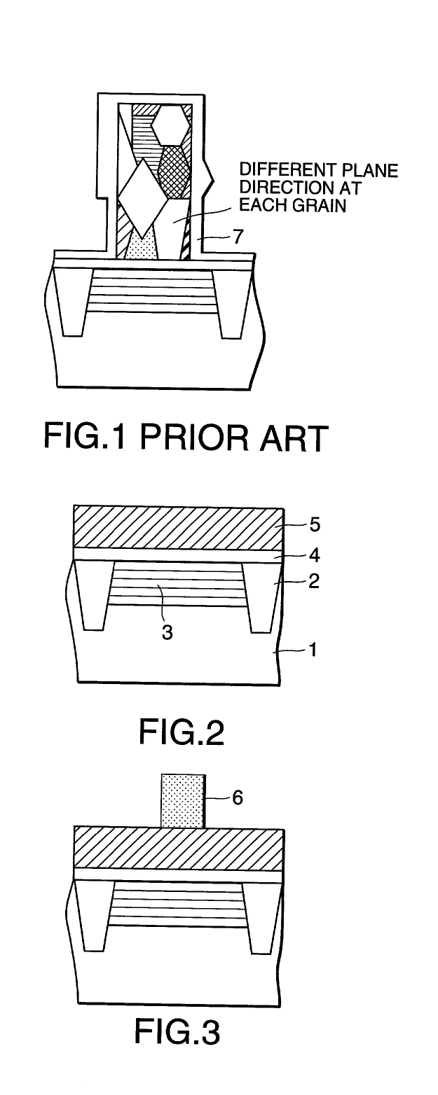

### DETAILED DESCRIPTION OF THE INVENTION

Next, referring to the drawings, the present invention will be described.

In this embodiment, the present invention will be described with an N-channel metal oxide semiconductor field effect transistor (NMOSFET) which has a design rule of less than 0.1 μm and is driven by a power supply voltage of 1.0V as an example.

As shown in FIG. 2, element isolation films 2 are formed in a P-type silicon substrate 1, and a P well 3 is formed in the NMOSFET formation region by implanting a P-type impurity such as boron of 150 keV to a concentration of 2E13/cm² and of 15 keV to a concentration of 5E12/cm².

Following that, a gate insulation film 4 of the NMOSFET, such as oxynitride film, is formed to a thickness of 15 Å by rapid thermal processing (RTP), and polysilicon 5 which is to become the gate electrode is deposited to a thickness of 150 nm by chemical vapor deposition (CVD).

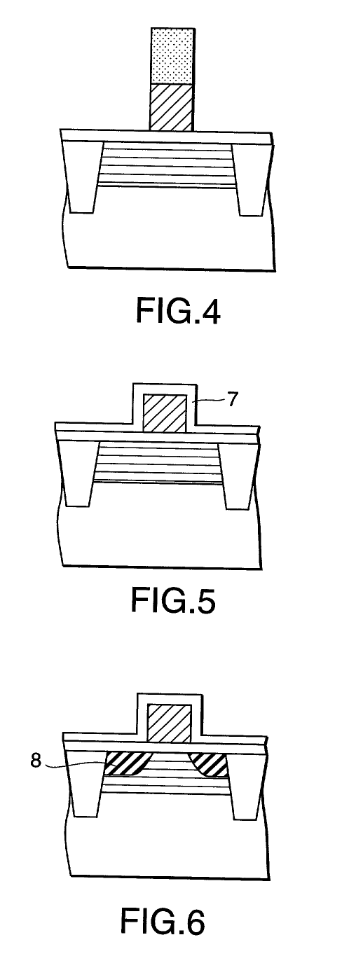

Next, as shown in FIG. 3, a PR mask 6 is formed by an exposure method, and the gate is patterned as shown in FIG. 4.

Next, a step which features the present invention is introduced. That is, as shown in FIG. 5, a side face oxide film of the gate electrode of the MOSFET is formed by an oxidation method, such as in-situ steam generation (ISSG), which makes the film thickness along the gate electrode uniform, and source/drain extension regions are formed by implanting an impurity into the source/drain regions using the gate electrode having the uniform thickness side face oxide film as a mask. Following that, a side face oxide film 7 is formed to a thickness of 2 nm by a normal oxidation method such as the conventional dry oxidation, wet oxidation (steam oxidation) or the like.

In the step of forming the oxide film on the side faces of the gate electrode, what is important is that oxidation is provided by the ISSG method. The oxidation mechanism by the ISSG method is characterized in that it is oxidation by radical oxidizing species generated in the combustion reaction of hydrogen and oxygen. This oxidation is referred to also as on-atom oxidation because it is a type of oxidation performed by direct participation of active oxidizing species on the atoms. An example of a rapid thermal processing apparatus which executes oxidation by the ISSG method is the rapid thermal processing apparatus XEplus (registered trademark) available from Applied Materials Inc. in California, U.S.A.

A lamp assembly of the apparatus is constituted by a plurality of lamps which are arranged on a chamber in the apparatus, for heating a semiconductor wafer placed in the chamber by irradiating it with light. The wafer is placed on a supporting ring and is rotated in order to uniformize the effect of irradiation with light. A plurality of optical probes (pyrometers) installed on the bottom part of the chamber detect radiation from various parts on the bottom face of the wager, and temperature signals are calculated from the results of the detection. Control signals for lamp drive units in various regions of the lamp assembly are generated by simultaneously processing these temperature signals, to control the temperature of the wafer to a uniform value. An H₂ containing gas and an O₂ containing gas are introduced into the chamber, and they are brought into reaction to generate steam (ISSG) in the chamber where the semiconductor wafer on which an oxide film is to be formed is arranged.

In the present embodiment, using such an apparatus, an oxide film 7 with, thickness of 20 Å is formed on the side faces of the gate by bringing 4.95 L of oxygen and hydrogen of 5% concentration (diluted with nitrogen) for 1 ls in an atmosphere at 950° C. and 13 Torr. The uniformity of the oxide film is about 1%. In contrast, the uniformity of the oxide film by the conventional oxidation method is about 2%. Since the uniformity of the oxide film, namely, the variation in the oxide film affects as it is the variation in the source-drain extension, variation in the transistor properties according to this invention are small in the formation of a hyperfine semiconductor device.

Next, as shown in FIG. 6, source-drain extension regions 8 are formed by implanting an N-type impurity such as As to a concentration of 5E14/cm² with an energy of 5 keV. Similar method can also be applied to the case of a P-channel MOSFET.

The present invention can be applied also to an example of giving side face oxidation to a gate electrode in a process of pre-doping the gate by using polysilicon for the gate electrode. What is meant by the pre-doping is a process in which an impurity is doped into polysilicon prior to patterning of the gate electrode for the purpose of depletion improvement of the gate electrode, in addition to the normal doping of the impurity into polysilicon simultaneous with the source-drain formation. The pre-doping has an advantage in allowing an impurity design exclusively for the gate depletion separately from the source-drain design.

The conventional technology has problems in that, a doped polysilicon electrode tends to react with an etching gas and is apt to be etched at gate etching, and further, is affected strongly by the difference between individual grains of polysilicon at side face oxidation, resulting in the difference in the thickness of the side face oxide film for individual grains. In contrast, by applying side face oxidation to the gate electrode by employing the ISSG method in the pre-doping processing, it is possible to make the thickness of the side face oxide film constant.

As described in the above, according to the present invention, by adopting the ISSG method in performing the side face oxidation of the gate electrode of a MOSFET composed of polysilicon, the thickness of the side face oxide film can be formed uniform without being affected by the plane direction of individual grains of polysilicon, and it is possible to suppress the nonuniformity of impurity implantation at formation of the source-drain extension regions caused by the nonunifomity in the thickness of the side face oxide film. Since it is a type of oxidation using radical species different from the normal oxidation method of dry oxidation or wet oxidation, it is possible to form a film of uniform thickness without being affected by the plane direction of polysilicon.

Although the invention has been described with reference to a specific embodiment, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method of manufacturing semiconductor devices including a MOSFET comprising,
a step of selectively forming element isolation films on the surface of a semiconduct or substrate of first conductivity type,,
a step of forming a well region of the first conductivity type in a selected region between said element isolation films,
a step of forming a gate insulation film on the surface of said semiconductor substrate and forming a first conductive film composed of amorphous silicon on top of it,
a step of forming a gate electrode in a portion above said well region of the first conductivity type by patterning said first conductive film,
a step of forming an oxide film on the side faces of said gate electrode by in-situ steam generation (ISSG) method, and
a step of forming a source region and a drain region formed in self-alignment with said gate electrode by implanting an impurity of second conductivity type into said well region of the first conductivity type using said gate electrode and the oxide film on its side faces as a mask.

2. The method of manufacturing a semiconductor device as claimed in claim 1, wherein said first conductive film is composed of polysilicon or silicon germanium.

3. The method of manufacturing a semiconductor device as claimed in claim 1, wherein said oxide film on said gate electrode side faces is formed by the ISSG method by bringing 4.95 liters of oxygen and hydrogen of 5% concentration (diluted with nitrogen) into reaction in an atmosphere at 950° C. and 13 Torr.
